(19) United States
(12) Patent Application Publication
(10) Pub. No.: US 2025/0357112 A1
(43) Pub. Date: Nov. 20, 2025

(54) PLASMA-ENHANCED SILICON NITRIDE DEPOSITION

(71) Applicant: Applied Materials, Inc., Santa Clara, CA (US)

(72) Inventors: Hao Zhang, San Jose, CA (US); Hanhong Chen, Milpitas, CA (US); Tao Hu, Sunnyvale, CA (US); Guan-Wen Liu, San Jose, CA (US); Chi-Chou Lin, San Jose, CA (US)

(73) Assignee: Applied Materials, Inc., Santa Clara, CA (US)

(21) Appl. No.: 18/664,706

(22) Filed: May 15, 2024

(51) Int. Cl. H01L 21/02

(52) U.S. Cl. CPC H01L 21/0234; H01L 21/0217; H01L 21/02178; H01L 21/02274; H01L 21/0228

(57) ABSTRACT

Methods of depositing a silicon nitride (SiₓN_{y}) film directly on an aluminum oxide (Al₂O₃) film to form a film stack are disclosed. Exemplary methods include, optionally, treating the aluminum oxide (Al₂O₃) film formed on a semiconductor substrate with a plasma comprising nitrogen (N₂) (e.g., a microwave plasma) for a time period in a range of from 0.1 seconds to 2 minutes. The methods further include depositing the silicon nitride (SiₓN_{y}) film directly on the aluminum oxide (Al₂O₃) film by plasma-enhanced atomic layer deposition (PEALD).

### TECHNICAL FIELD

Embodiments of the disclosure generally relate to the field of semiconductor device manufacturing. More particularly, embodiments of the disclosure are directed to methods of depositing silicon nitride (SiₓN_{y}) directly on aluminum oxide (Al₂O₃) by plasma-enhanced atomic layer deposition (PEALD).

### BACKGROUND

Silicon nitride (SiₓN_{y}) films have attractive dielectric material properties. These films have been proposed and tested for applications from front-end of line (FEOL) to back-end of line (BEOL) processes and parts of semiconductor devices and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

Low temperature, e.g., less than or equal to 600° C., atomic layer deposition (ALD) of silicon nitride (SiₓN_{y}) films are used in many semiconductor applications. Without intending to be bound by any particular theory, it is thought that many of these low temperature applications are deposited by plasma-enhanced ALD (PEALD) due to poor film quality by low temperature thermal processes, e.g., a thermal ALD process which does not involve the use of plasma.

PEALD film quality varies based on the surface (e.g., substrate) on which the film is deposited. In particular, it has been found that PEALD film quality varies based on the material of the substrate and the geometry of the substrate, for example.

Silicon (Si) substrates are widely used in semiconductor and microelectronic manufacturing applications, including in silicon nitride (SiₓN_{y}) deposition. Generally, a native oxide layer (e.g., an interfacial layer comprising silicon oxide (SiOx)) having a thickness of only a few Angstroms (such as less than or equal to 5 Angstroms) is present on the silicon (Si) substrate. A film stack comprising a silicon nitride (SiₓN_{y}) film directly on an aluminum oxide (Al₂O₃) film on a silicon (Si) substrate can be used in a number in semiconductor and microelectronic manufacturing applications.

As a result of depositing an aluminum oxide (Al₂O₃) film on a silicon (Si) substrate by atomic layer deposition (ALD), hydrogen atoms are incorporated into the aluminum oxide (Al₂O₃) film in the form of hydroxyl groups. The hydroxyl groups are able to diffuse to the interfacial layer. It is thought that the hydroxyl groups diffuse through the aluminum oxide (Al₂O₃) film in the form of atomic hydrogen. It has been found that the atomic hydrogen that has diffused into the interfacial layer can act as a passivation agent. As such, the atomic hydrogen is able to react with larger molecules (e.g., molecular hydrogen) that are trapped at the interface of the silicon (Si) substrate and the interfacial layer. The interfacial layer can act as a freeway for the atomic hydrogen and molecular hydrogen, enabling fast lateral diffusion. During annealing of the substrate, it is thought that the amount of molecules that are trapped at the interface of the silicon (Si) substrate and the interfacial layer increases, creating an accumulation of the larger molecules (e.g., molecular hydrogen) on the interface layer. This accumulation can cause delamination of the aluminum oxide (Al₂O₃) film from the interfacial layer, causing “blisters” to be formed.

As used herein, the term “blister” refers to a surface defect with a top surface having a convex shape or converging shape relative to the surface on which the blister forms. The top surface of the blister and the surface on which the blister forms define an opening, and one or more molecules may move into the opening of the blister. For example, the trapped molecules (e.g., molecular hydrogen) can diffuse into the blisters.

The blister formation process is thought to be irreversible. That is, once a blister is formed, regardless of whether the blister causes film delamination or not, the blisters remain in the interfacial layer and/or aluminum oxide (Al₂O₃) film.

Then, a silicon nitride (SiₓN_{y}) film may be deposited directly on the aluminum oxide (Al₂O₃) film (which may have blisters) by PEALD. Unfortunately, PEALD of a high quality silicon nitride (SiₓN_{y}) film directly on the aluminum oxide (Al₂O₃) film remains a challenge due to the presence of blisters.

Current PEALD approaches, e.g., (1) exposure to silicon-containing precursor, purge, exposure to thermal ammonia (NH₃), followed by nitrogen (N₂) plasma, and/or (2) exposure to silicon-containing precursor, purge, exposure to ammonia (NH₃) plasma, and purge, have been found to produce blisters at an interface of the aluminum oxide (Al₂O₃) film and the silicon nitride (SiₓN_{y}) film. In particular, it has been found that the exposure to ammonia (NH₃) plasma generates free hydrogen radicals, and these radicals penetrate the aluminum oxide (Al₂O₃) film in the form of atomic hydrogen atoms. Some of the atomic hydrogen atoms travel through the silicon nitride (SiₓN_{y}) film and form molecular hydrogen. Molecular hydrogen has been found to cause local high stress and form blisters in the aluminum oxide (Al₂O₃) film. Therefore, current PEALD approaches for depositing silicon nitride (SiₓN_{y}) have been found to exacerbate the blister issue.

Accordingly, there is a need for improved processes of depositing silicon nitride (SiₓN_{y}) directly on aluminum oxide (Al₂O₃) without forming blisters.

### SUMMARY

One or more embodiments of the disclosure are directed to a method comprising: depositing an aluminum oxide (Al₂O₃) film on a semiconductor substrate; and depositing a silicon nitride (SiₓN_{y}) film directly on the aluminum oxide (Al₂O₃) film.

Additional embodiments of the disclosure are directed to a method comprising treating an aluminum oxide (Al₂O₃) film on a semiconductor substrate with a plasma comprising nitrogen (N₂) for a time period in a range of from 0.1 seconds to 2 minutes. In some embodiments, the plasma comprises a microwave plasma generated by a microwave plasma source. The method further comprises depositing a silicon nitride (SiₓN_{y}) film directly on the aluminum oxide (Al₂O₃) film. In some embodiments, depositing the silicon nitride (SiₓN_{y}) film comprises a plasma-enhanced atomic layer deposition (PEALD) process comprising: exposing the semiconductor substrate to a silicon-containing precursor; and exposing the semiconductor substrate to a nitrogen-containing plasma mixture comprising argon (Ar) and one or more of ammonia (NH₃) or nitrogen (N₂), wherein the semiconductor substrate is exposed to the nitrogen-containing plasma mixture for a time period in a range of from 0.2 seconds to 4 seconds, and the nitrogen-containing plasma mixture comprises a microwave plasma generated by the microwave plasma source.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of the present disclosure and are therefore not to be considered limiting of its scope, for the disclosure may admit to other equally effective embodiments.

FIG. 1 illustrates a substrate according to the prior art;

FIG. 2A illustrates a process flow diagram of a method in accordance with one or more embodiments of the disclosure;

FIG. 2B illustrates a cross-sectional schematic view of a semiconductor substrate having an aluminum oxide (Al₂O₃) film deposited thereon in accordance with one or more embodiments of the disclosure;

FIG. 2C illustrates treatment of the aluminum oxide (Al₂O₃) film of FIG. 2B in accordance with one or more embodiments of the disclosure;

FIG. 2D illustrates deposition of a silicon nitride (SiₓN_{y}) film directly on the treated aluminum oxide (Al₂O₃) film of FIG. 2C in accordance with one or more embodiments of the disclosure;

FIG. 2E illustrates a cross-sectional schematic view of a semiconductor substrate having a feature formed therein in accordance with one or more embodiments of the disclosure;

FIG. 2F illustrates deposition of an aluminum oxide (Al₂O₃) film on the semiconductor substrate of FIG. 2E in accordance with one or more embodiments of the disclosure;

FIG. 2G illustrates treatment of the aluminum oxide (Al₂O₃) film of FIG. 2F in accordance with one or more embodiments of the disclosure;

FIG. 2H illustrates deposition of a silicon nitride (SiₓN_{y}) film directly on the treated aluminum oxide (Al₂O₃) film of FIG. 2G in accordance with one or more embodiments of the disclosure;

FIG. 3 illustrates a schematic representation of a processing tool comprising a modular high-frequency emission source with a plasma showerhead assembly that comprises a plurality of applicators in accordance with one or more embodiments of the disclosure;

FIG. 4 illustrates a block diagram of a high-frequency emission module in accordance with one or more embodiments of the disclosure;

FIG. 5 illustrates a schematic exploded perspective view of the plasma showerhead assembly of FIG. 3 in accordance with one or more embodiments of the disclosure; and

FIG. 6 illustrates a cross-sectional view of a processing tool in accordance with o one or more embodiments of the disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. As used herein, the term “thermal process(es)” refers to a deposition technique that does not involve the use of plasma. As used herein, the term “plasma” refers to a composition have ionically charged species and uncharged neutral and radical species.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced atomic layer deposition (PEALD) are conformal. As used herein, as will be understood by the skilled artisan, a layer which is “conformal” or “conformally deposited” refers to a layer where the thickness is about the same throughout. A layer/film which is conformal varies in thickness by less than or equal to about 5%, 2%, 1% or 0.5%.

Plasma-enhanced atomic layer deposition (PEALD) methods add a plasma exposure to traditional ALD methods. In some PEALD methods, a nitrogen source is provided as the plasma. The primary benefit of PEALD methods is the relatively low substrate temperature, e.g., less than or equal to 600° C., during processing.

Embodiments of the disclosure are directed to provide methods of depositing silicon nitride (SiₓN_{y}) directly on aluminum oxide (Al₂O₃) for semiconductor and microelectronic manufacturing applications. Some embodiments advantageously provide methods of depositing silicon nitride (SiₓN_{y}) directly on aluminum oxide (Al₂O₃) for FEOL and BEOL processes and parts.

Embodiments of the disclosure advantageously provide methods of depositing silicon nitride (SiₓN_{y}) directly on aluminum oxide (Al₂O₃) without forming blisters. Some embodiments advantageously provide methods of depositing silicon nitride (SiₓN_{y}) directly on aluminum oxide (Al₂O₃) without having defects at an interface of the aluminum oxide (Al₂O₃) and the interfacial layer. Some embodiments advantageously provide plasma sequences for depositing a uniform silicon nitride (SiₓN_{y}) film directly on aluminum oxide (Al₂O₃) without forming blisters.

Additional embodiments of the disclosure provide a plasma showerhead assembly, e.g., an assembly, for a processing tool. In one or more embodiments, the assembly comprises a conductive plate and a dielectric faceplate.

In one or more embodiments, the conductive plate includes a first surface and a second surface opposite to the first surface defining a conductive plate thickness, a plurality of resonator openings extending from the first surface through the conductive plate to the second surface of the conductive plate, gas channels within the conductive plate thickness, a plurality of conductive plate gas openings on the second surface of the conductive plate in fluid communication with the gas channels within the conductive plate thickness.

In one or more embodiments, the dielectric faceplate comprises a first surface and a second surface opposite to the first surface defining a dielectric faceplate thickness, a plurality of dielectric resonator protruding from the first surface and configured so that the resonators fit into the plurality of the resonator openings of the conductive plate when assembled, each resonator having a geometric center; and a plurality of dielectric faceplate gas openings extending through the dielectric faceplate thickness.

In one or more embodiments, the assembly comprises a plurality of o-rings surrounding the conductive plate gas openings and the dielectric faceplate gas openings, wherein the dielectric faceplate gas openings are in fluid communication with the conductive plate gas openings and the o-rings are configured to seal the dielectric faceplate gas openings and the conductive plate gas openings from atmospheric pressure.

The assembly described herein is a microwave plasma source that may be used to generate a microwave plasma of any of the plasma compositions described herein. Advantageously, the energy of ions in a microwave plasma can be tuned low enough that it does not substantially damage dielectric materials. Further, the disclosed methods are self-limiting by only affecting the silicon nitride (SiₓN_{y}) films deposited and not the other layers, such as a dielectric layer, in the structures.

The embodiments of the disclosure are described by way of the Figures, which illustrate processes, substrates, and apparatuses in accordance with one or more embodiments of the disclosure. The processes and resulting substrates shown are merely illustrative of the disclosed processes, and the skilled artisan will recognize that the disclosed processes are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

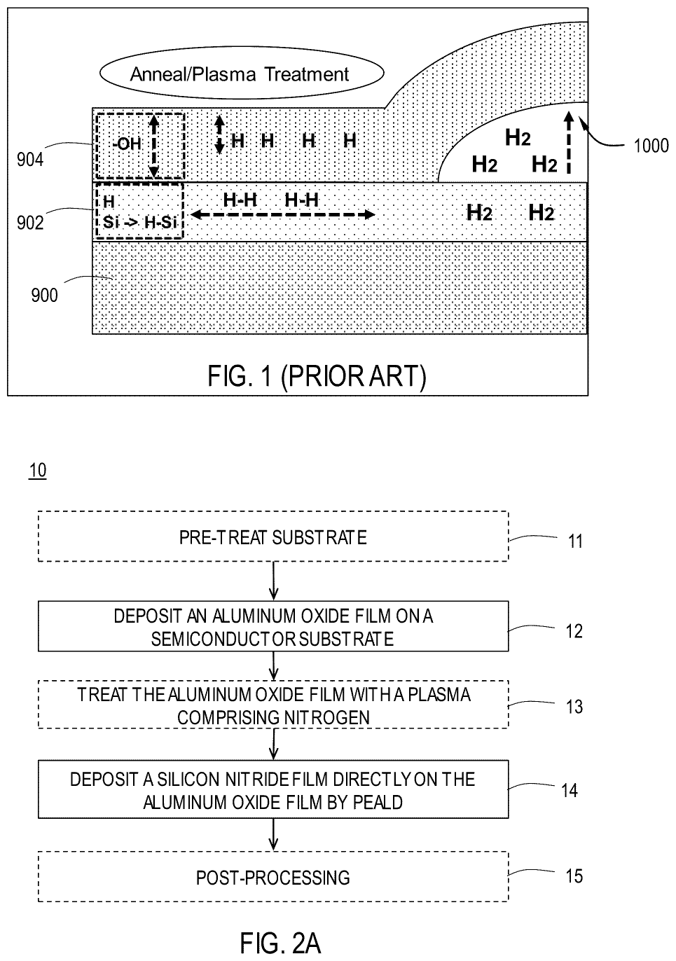

FIG. 1 illustrates a substrate 900 according to the prior art. The substrate 900 comprises silicon (Si). Accordingly, as described herein, the “substrate 900” can be interchangeably referred to as “silicon (Si) substrate 900.” Directly on the substrate 900 is a native oxide layer, e.g., an interfacial layer 902 comprising silicon oxide (SiOx) and having a thickness of only a few Angstroms (such as less than or equal to 5 Angstroms). As a result of depositing an aluminum oxide (Al₂O₃) film 904 on the silicon (Si) substrate 900 by atomic layer deposition (ALD), hydrogen atoms are incorporated into the aluminum oxide (Al₂O₃) film 904 in the form of hydroxyl groups (denoted by “—OH”). The hydrogen atoms are able to diffuse through the aluminum oxide (Al₂O₃) film 904 to the interfacial layer 902 in the form of atomic hydrogen (denoted by “H”). It has been found that the atomic hydrogen that has diffused into the interfacial layer 902 can act as a passivation agent. As such, the atomic hydrogen is able to react with larger molecules (e.g., molecular hydrogen (denoted by “H—H” or “H₂”) that are trapped at the interface of the silicon (Si) substrate 900 and the interfacial layer 902. The interfacial layer 902 acts as a freeway for the atomic hydrogen (“H”) and molecular hydrogen (“H—H” or “H₂”), enabling fast lateral diffusion. During annealing of the substrate 900, it is thought that the amount of molecules that are trapped at the interface of the silicon (Si) substrate 900 and the interfacial layer 902 increases, creating an accumulation of the larger molecules (e.g., molecular hydrogen) on the interfacial layer 902. This accumulation can cause delamination of the aluminum oxide (Al₂O₃) film 904 from the interfacial layer 902, causing one or more blisters 1000 to be formed.

FIG. 1 illustrates one blister 1000 for illustrative purposes. Any number of blisters 1000 may be formed as a result of depositing the aluminum oxide (Al₂O₃) film 904 on the silicon (Si) substrate 900 by atomic layer deposition (ALD). In the illustrated embodiment of FIG. 1, molecular hydrogen (“H—H” or “H₂”) is shown as traveling from the interfacial layer 902 to the opening of the blister 1000. Based upon the presence of one or more blisters 1000, the aluminum oxide (Al₂O₃) film 904 is not “continuous”, as the term “continuous” is used herein.

Then, a silicon nitride (SiₓN_{y}) film can be deposited directly on the aluminum oxide (Al₂O₃) film (which has one or more blisters 1000) by PEALD. Unfortunately, PEALD of a high quality silicon nitride (SiₓN_{y}) film directly on the aluminum oxide (Al₂O₃) film remains a challenge due to the presence of blisters.

Current PEALD approaches, e.g., (1) exposure to silicon-containing precursor, purge, exposure to thermal ammonia (NH₃), followed by nitrogen (N₂) plasma, or (2) exposure to silicon-containing precursor, purge, exposure to ammonia (NH₃) plasma, and purge, have been found to produce blisters at an interface of the aluminum oxide (Al₂O₃) film 904 and the silicon nitride (SiₓN_{y}) film. In particular, it has been found that the exposure to ammonia (NH₃) plasma generates free hydrogen radicals, and these radicals can penetrate the aluminum oxide (Al₂O₃) film 904 in the form of atomic hydrogen atoms. Some of the atomic hydrogen atoms (“H”) travel through the silicon nitride (SiₓN_{y}) film and form molecular hydrogen (“H—H” or “H₂”). Molecular hydrogen (“H—H” or “H₂”) has been found to cause local high stress and form blisters 1000 in the aluminum oxide (Al₂O₃) film 904, as shown in FIG. 1. Therefore, current PEALD approaches for depositing silicon nitride (SiₓN_{y}) have been found to exacerbate the blister issue.

Embodiments of the disclosure advantageously provide methods of depositing silicon nitride (SiₓN_{y}) directly on aluminum oxide (Al₂O₃) without forming blisters.

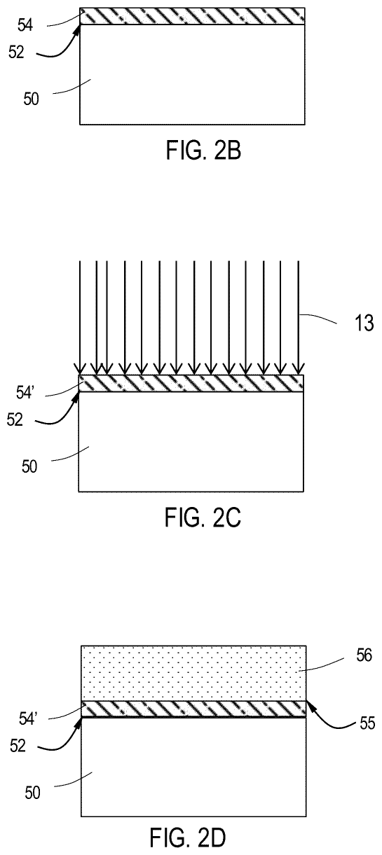

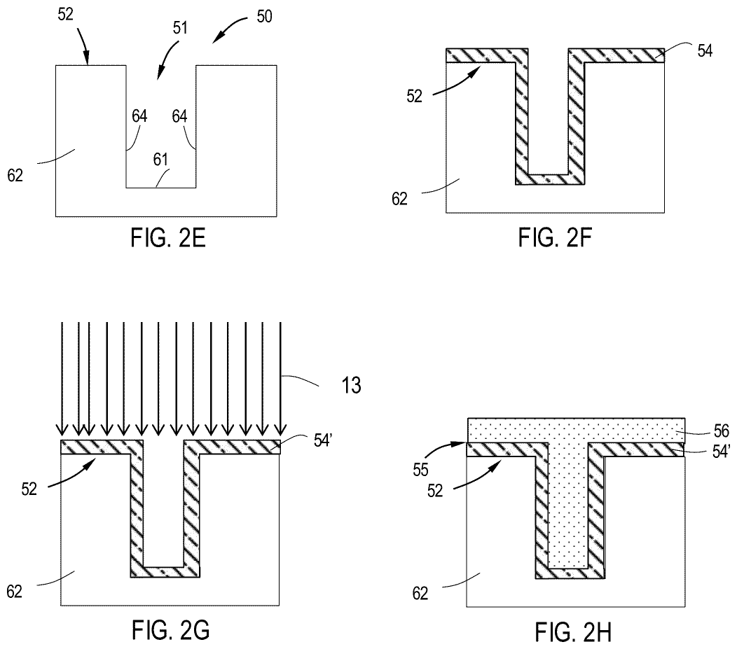

FIG. 2A illustrates a process flow diagram of a method 10 in accordance with one or more embodiments of the disclosure. The method 10 may be performed at any suitable processing conditions, and the processing conditions may vary depending upon the application for which the substrate and any layers formed thereon are used.

FIG. 2B-2H illustrate cross-sectional schematic views of the semiconductor substrate 50. The semiconductor substrate 50 can be any suitable substrate material. In one or more embodiments, the semiconductor substrate 50 comprises a semiconductor material, e.g., one or more of silicon (Si), germanium (Ge), silicon germanium (SiGe), and/or a metal material, e.g., one or more of tungsten (W), nickel (Ni), cobalt (Co), or titanium (Ti). In one or more embodiments, the semiconductor substrate 50 comprises one or more of silicon (Si) or silicon oxide (SiOx).

The method 10 begins by optionally pre-treating the semiconductor substrate 50 at operation 11. In one or more embodiments of FIG. 2A, the dashed lines are used to denote that the stated operation is optional.

In one or more embodiments, the semiconductor substrate 50 is a silicon (Si) substrate. In one or more embodiments, a native oxide layer (e.g., an interfacial layer comprising silicon oxide (SiOx)) having a thickness of only a few Angstroms (such as less than or equal to 5 Angstroms) is present on the semiconductor substrate 50. In one or more embodiments, the semiconductor substrate 50 includes one or more of silicon (Si) and silicon oxide (SiOx).

The pre-treatment of operation 11 can be any suitable pre-treatment known to the skilled artisan. Suitable pre-treatments include, but are not limited to, pre-heating, cleaning, soaking, or native oxide removal, as examples.

Referring to FIGS. 2A and 2B, the method 10 according to one or more embodiments comprises depositing an aluminum oxide (Al₂O₃) film 54 directly on a top surface 52 of the semiconductor substrate 50 at operation 12.

The aluminum oxide (Al₂O₃) film 54 can be deposited by any suitable deposition technique. In one or more embodiments, the aluminum oxide (Al₂O₃) film 54 is deposited on or directly on the semiconductor substrate 50 by atomic layer deposition (ALD). Any suitable precursors and/or reactants can be used to deposit the aluminum oxide (Al₂O₃) film 54. In one or more embodiments, the ALD to form the aluminum oxide (Al₂O₃) film 54 comprises exposing the semiconductor substrate 50 to an aluminum-containing precursor, purging, exposing the semiconductor substrate 50 to an oxygen-containing reactant, and purging.

The aluminum oxide (Al₂O₃) film 54 can be deposited at any suitable processing conditions. The processing conditions may vary based upon the particular application in which the aluminum oxide (Al₂O₃) film 54 is used. The aluminum oxide (Al₂O₃) film 54 may have any suitable thickness. In one or more embodiments, the aluminum oxide (Al₂O₃) film 54 has a thickness in a range of from 20 Angstroms to 100 Angstroms. The thickness of the aluminum oxide (Al₂O₃) film 54 may vary within the range of from 20 Angstroms to 100 Angstroms based upon the particular application in which the aluminum oxide (Al₂O₃) film 54 is used.

Referring to FIGS. 2A and 2C, the method 10 of one or more embodiments comprises optionally treating the aluminum oxide (Al₂O₃) film 54 at operation 13 to form a treated aluminum oxide (Al₂O₃) film 54′. The treatment of operation 13 is denoted by the arrows shown in FIGS. 2C and 2G.

The plasma used to treat the aluminum oxide (Al₂O₃) film 54 at operation 13 to form the treated aluminum oxide (Al₂O₃) film 54′ comprises nitrogen (N₂). In some embodiments, the plasma used to treat the aluminum oxide (Al₂O₃) film 54 at operation 13 to form the treated aluminum oxide (Al₂O₃) film 54′ consists essentially of nitrogen (N₂). In some embodiments, the plasma used to treat the aluminum oxide (Al₂O₃) film 54 at operation 13 to form the treated aluminum oxide (Al₂O₃) film 54′ consists of nitrogen (N₂).

In some embodiments, the plasma used to treat the aluminum oxide (Al₂O₃) film 54 at operation 13 to form the treated aluminum oxide (Al₂O₃) film 54′ comprises nitrogen (N₂) and a non-reactive species, such as, for example, an inert gas.

In some embodiments, the plasma used to treat the aluminum oxide (Al₂O₃) film 54 at operation 13 to form the treated aluminum oxide (Al₂O₃) film 54′ comprises nitrogen (N₂) and argon (Ar). In some embodiments, the plasma used to treat the aluminum oxide (Al₂O₃) film 54 at operation 13 to form the treated aluminum oxide (Al₂O₃) film 54′ consists essentially of nitrogen (N₂) and argon (Ar). In some embodiments, the plasma used to treat the aluminum oxide (Al₂O₃) film 54 at operation 13 to form the treated aluminum oxide (Al₂O₃) film 54′ consists of nitrogen (N₂) and argon (Ar). In some embodiments, the plasma used to treat the aluminum oxide (Al₂O₃) film 54 at operation 13 to form the treated aluminum oxide (Al₂O₃) film 54′ comprises nitrogen (N₂) and helium (He). In some embodiments, the plasma used to treat the aluminum oxide (Al₂O₃) film 54 at operation 13 to form the treated aluminum oxide (Al₂O₃) film 54′ consists essentially of nitrogen (N₂) and helium (He). In some embodiments, the plasma used to treat the aluminum oxide (Al₂O₃) film 54 at operation 13 to form the treated aluminum oxide (Al₂O₃) film 54′ consists of nitrogen (N₂) and helium (He).

In one or more embodiments, any suitable plasma source, including, but not limited to a remote plasma source, an inductively coupled plasma (ICP) source, a capacitively coupled plasma (CCP) source, or a microwave plasma source, may be used to generate any of the disclosed plasmas and/or plasma mixtures.

The skilled artisan will appreciate that any remote plasma source, inductively coupled plasma (ICP) source, capacitively coupled plasma source (CCP) source, or microwave plasma source that is suitable for generating any of the disclosed plasmas and/or plasma mixtures and may be implemented for the disclosed methods.

One or more embodiments of the present disclosure include modular microwave plasma processing tools. Modular microwave plasma sources have a high plasma density and very low plasma potential (e.g., less than or equal to 10 eV).

In one or more embodiments, the plasma comprising nitrogen (N₂) is a microwave plasma generated by a microwave plasma source, such as, for example, a modular microwave plasma source as described herein.

In one or more embodiments, the aluminum oxide (Al₂O₃) film 54 is treated with a plasma comprising nitrogen (N₂) for a time period in a range of from 0.1 seconds to 2 minutes to form the treated aluminum oxide (Al₂O₃) film 54′. In one or more embodiments, the aluminum oxide (Al₂O₃) film 54 is treated with a plasma comprising nitrogen (N₂) (a microwave plasma generated by a microwave plasma source) for a time period in a range of from 0.1 seconds to 2 minutes to form the treated aluminum oxide (Al₂O₃) film 54′.

In one or more embodiments, the treated aluminum oxide (Al₂O₃) film 54′ has a thickness in a range of from 20 Angstroms to 100 Angstroms. The thickness of the treated aluminum oxide (Al₂O₃) film 54′ may vary within the range of from 20 Angstroms to 100 Angstroms based upon the particular application in which the treated aluminum oxide (Al₂O₃) film 54′ is used.

It has been advantageously found that treating the aluminum oxide (Al₂O₃) film 54 with a plasma comprising nitrogen (N₂) (a microwave plasma generated by a microwave plasma source) for a time period in a range of from 0.1 seconds to 2 minutes to form the treated aluminum oxide (Al₂O₃) film 54′ provides an interface between the treated aluminum oxide (Al₂O₃) film 54′ and the semiconductor substrate 50 that is free of blisters.

The method 10 comprises at operation 14, depositing a silicon nitride (SiₓN_{y}) film 56 directly on the aluminum oxide (Al₂O₃) film 54 by a plasma-enhanced atomic layer deposition (PEALD) process. In embodiments where the aluminum oxide (Al₂O₃) film 54 is treated to form the treated aluminum oxide (Al₂O₃) film 54′ at operation 13, as in FIG. 2D, a silicon nitride (SiₓN_{y}) film 56 is deposited directly on a top surface 55 of the treated aluminum oxide (Al₂O₃) film 54′ by a plasma-enhanced atomic layer deposition (PEALD) process.

In one or more embodiments, the PEALD process begins by exposing the semiconductor substrate 50 to a silicon-containing precursor. The silicon-containing precursor may be any suitable precursor that includes silicon. In some embodiments, the silicon-containing precursor includes, but is not limited to, one or more of a silane (SiₓH_{y}), a chlorosilane (SiₓH_{y}Cl_{z}), or an iodosilane (SiₓH_{y}I_{z}). In some embodiments, the silicon-containing precursor includes one or more of silane (SiH₄), disilane (Si₂H₆), chlorosilane (H₃SiCl), dichlorosilane (H₂SiCl₂), trichlorosilane (HSiCl₃), tetrachlorosilane (HSiCl₄), iodosilane (H₃ISi), diiodosilane (H₂I₂Si), triiodosilane (HI₃Si), or tetraiodosilane (I₄Si). In some embodiments, the silicon-containing precursor includes bis(diethylamino)silane (BDEAS).

The PEALD process optionally includes purging the semiconductor substrate 50 after exposing the semiconductor substrate 50 to the silicon-containing precursor.

The PEALD process comprises exposing the semiconductor substrate 50 to a nitrogen-containing plasma mixture comprising argon (Ar) and one or more of ammonia (NH₃) or nitrogen (N₂) to deposit the silicon nitride (SiₓN_{y}) film 56 directly on the aluminum oxide (Al₂O₃) film 54, or, in embodiments where the aluminum oxide (Al₂O₃) film 54 is treated to form the treated aluminum oxide (Al₂O₃) film 54′ at operation 13, as in FIG. 2D, to deposit the silicon nitride (SiₓN_{y}) film directly on the top surface 55 of the treated aluminum oxide (Al₂O₃) film 54′.

In one or more embodiments, the nitrogen-containing plasma mixture comprises nitrogen (N₂) and argon (Ar). In one or more embodiments, the nitrogen-containing plasma mixture consists essentially of nitrogen (N₂) and argon (Ar). In one or more embodiments, the nitrogen-containing plasma mixture consists of nitrogen (N₂) and argon (Ar).

In one or more embodiments, the nitrogen-containing plasma mixture comprises ammonia (NH₃) and argon (Ar). In one or more embodiments, the nitrogen-containing plasma mixture consists essentially of ammonia (NH₃) and argon (Ar). In one or more embodiments, the nitrogen-containing plasma mixture consists of ammonia (NH₃) and argon (Ar).

The nitrogen-containing plasma mixture according to one or more embodiments of the disclosure can be generated by any suitable plasma source. In one or more embodiments, the nitrogen-containing plasma mixture is a microwave plasma generated by a microwave plasma source, such as, for example, a modular microwave plasma source as described herein.

The PEALD process optionally includes purging the semiconductor substrate 50 after exposing the semiconductor substrate 50 to the nitrogen-containing plasma mixture comprising argon (Ar) and one or more of ammonia (NH₃) or nitrogen (N₂) to form the silicon nitride (SiₓN_{y}) film 56.

The silicon nitride (SiₓN_{y}) film 56 may be formed at any suitable processing pressure and any suitable processing temperature. In one or more embodiments, the silicon nitride (SiₓN_{y}) film 56 is formed at a pressure in a range of from 0.1 Torr to 20 Torr. In one or more embodiments, the silicon nitride (SiₓN_{y}) film 56 is formed at a temperature in a range of from 100° C. to 600° C. In one or more embodiments, the silicon nitride (SiₓN_{y}) film 56 is formed at a temperature in a range of from 250° C. to 500° C.

In one or more embodiments, a silicon nitride (SiₓN_{y}) film deposited directly on an aluminum oxide (Al₂O₃) film, such as the silicon nitride (SiₓN_{y}) film 56 deposited directly on the aluminum oxide (Al₂O₃) film 54 or the treated aluminum oxide (Al₂O₃) film 54′ as described herein, may be collectively referred to as a “film stack.”

Further aspects of the disclosure pertain to a method that is part of a gap fill process. The disclosed methods may be utilized with any device nodes, but may be particularly advantageous in device nodes of about 25 nm or less, for example about 5 nm to about 25 nm. It will be appreciated by the skilled artisan that, in embodiments where the method 10 is part of a gap-fill process, the method 10 can include one or more subsequent operations, such as, for example, filling the gap with a conductive material to form an interconnect, and that the one or more subsequent operations can be performed without undue experimentation.

FIGS. 2E-2H illustrate cross-sectional schematic views of a semiconductor substrate 50 having a feature, e.g., a trench 51, having a top surface 52, two sidewalls 64 comprising, for example, a dielectric material, and a bottom 61 comprising, for example, a metallic material extending into the substrate.

In FIG. 2F, the aluminum oxide (Al₂O₃) film 54 is deposited directly on a top surface 52 of the semiconductor substrate 50, along the two sidewalls 64, and the bottom 61, in accordance with operation 12 of the method 10.

FIG. 2G illustrates the treatment process of operation 13, denoted by the arrows pointed towards a top surface of the aluminum oxide (Al₂O₃) film 54 to form the treated aluminum oxide (Al₂O₃) film 54′.

FIG. 2H illustrates deposition of the silicon nitride (SiₓN_{y}) film 56 directly on a top surface 55 of the treated aluminum oxide (Al₂O₃) film 54′ by the plasma-enhanced atomic layer deposition (PEALD) process of operation 14 of the method 10.

In one or more embodiments, the silicon nitride (SiₓN_{y}) film 56 on the top surface 55 of the treated aluminum oxide (Al₂O₃) film 54′ fills a portion of the feature, e.g., the trench 51. In one or more embodiments, the silicon nitride (SiₓN_{y}) film 56 on the top surface 55 of the treated aluminum oxide (Al₂O₃) film 54′ fills in a range of 10% to 90% of the feature, e.g., the trench 51. In one or more embodiments, the silicon nitride (SiₓN_{y}) film 56 and the treated aluminum oxide (Al₂O₃) film 54′ collectively fill in a range of 10% to 90% of the feature, e.g., the trench 51. In one or more embodiments, the silicon nitride (SiₓN_{y}) film 56 on the top surface 55 of the treated aluminum oxide (Al₂O₃) film 54′ fills the feature, e.g., the trench 51, in its entirety, as shown in the illustrated embodiment of FIG. 2H.

It has been found that using varying compositions of plasma for varying time periods in the PEALD process to deposit the silicon nitride (SiₓN_{y}) film 56 may advantageously result in no blisters being present in the film stack.

The PEALD process comprises: exposing the semiconductor substrate to a silicon-containing precursor; and exposing the semiconductor substrate to a nitrogen-containing plasma mixture comprising argon (Ar) and one or more of ammonia (NH₃) or nitrogen (N₂). In the PEALD process, the semiconductor substrate is exposed to the nitrogen-containing plasma mixture for a time period in a range of from 0.2 seconds to 4 seconds.

In some embodiments, and in one or more of the following examples, exposing the semiconductor substrate to the nitrogen-containing plasma mixture comprises a first plasma sequence and a second plasma sequence. The first plasma sequence comprises exposing the semiconductor substrate to nitrogen (N₂) and argon (Ar). The second plasma sequence comprises exposing the semiconductor substrate to ammonia (NH₃) and argon (Ar). In some embodiments, and in one or more of the following examples, the first plasma sequence can be performed prior to the second plasma sequence, or vice versa.

In some embodiments, and in one or more of the following examples, exposing the semiconductor substrate to the nitrogen-containing plasma mixture further comprises a third plasma sequence. The third plasma sequence comprises exposing the semiconductor substrate to nitrogen (N₂) and argon (Ar).

The disclosure will now be described with reference to the following examples.

### EXAMPLES

### Example 1—Exposure to First Plasma Sequence, Followed by Exposure to Second Plasma Sequence

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 0.35 seconds, followed by exposing the semiconductor substrate to a plasma mixture of ammonia (NH₃), nitrogen (N₂), and argon (Ar) (e.g., the second plasma sequence) for a time period of about 0.65 seconds, without treating the aluminum oxide (Al₂O₃) film, resulted in the presence of blisters in the film stack.

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 0.65 seconds, followed by exposing the semiconductor substrate to a plasma mixture of ammonia (NH₃), nitrogen (N₂), and argon (Ar) (e.g., the second plasma sequence) for a time period of about 0.35 seconds, without treating the aluminum oxide (Al₂O₃) film, advantageously resulted in no blisters being present in the film stack.

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 0.8 seconds, followed by exposing the semiconductor substrate to a plasma mixture of ammonia (NH₃), nitrogen (N₂), and argon (Ar) (e.g., the second plasma sequence) for a time period of about 0.4 seconds, without treating the aluminum oxide (Al₂O₃) film, advantageously resulted in no blisters being present in the film stack.

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 1.5 seconds, followed by exposing the semiconductor substrate to a plasma mixture of ammonia (NH₃), nitrogen (N₂), and argon (Ar) (e.g., the second plasma sequence) for a time period of about 0.8 seconds, without treating the aluminum oxide (Al₂O₃) film, resulted in the presence of blisters in the film stack.

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 2 seconds, followed by exposing the semiconductor substrate to a plasma mixture of ammonia (NH₃), nitrogen (N₂), and argon (Ar) (e.g., the second plasma sequence) for a time period of about 0.4 seconds, including treating the aluminum oxide (Al₂O₃) film with a plasma comprising nitrogen (N₂) prior to the silicon nitride (SiₓN_{y}) deposition in accordance with one or more embodiments of the present disclosure, advantageously resulted in no blisters being present in the film stack.

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 3 seconds, followed by exposing the semiconductor substrate to a plasma mixture of ammonia (NH₃), nitrogen (N₂), and argon (Ar) (e.g., the second plasma sequence) for a time period of about 0.4 seconds, including treating the aluminum oxide (Al₂O₃) film with a plasma comprising nitrogen (N₂) prior to the silicon nitride (SiₓN_{y}) deposition in accordance with one or more embodiments of the present disclosure, advantageously resulted in no blisters being present in the film stack.

### Example 2—Exposure to Second Plasma Sequence, Followed by Exposure to First Plasma Sequence

It has been found that exposing a semiconductor substrate (having an aluminum oxide (Al₂O₃) film formed directly on the semiconductor substrate) to a plasma mixture of ammonia (NH₃), nitrogen (N₂), and argon (Ar) (e.g., the second plasma sequence) for a time period of about 0.65 seconds, followed by exposing the semiconductor substrate to a plasma comprising nitrogen (N₂) and argon (Ar) (e.g., the first plasma sequence) for a time period of about 0.35 seconds, without treating the aluminum oxide (Al₂O₃) film, resulted in the presence of blisters in the film stack.

It has been found that exposing a semiconductor substrate (having an aluminum oxide (Al₂O₃) film formed directly on the semiconductor substrate) to a plasma mixture of ammonia (NH₃), nitrogen (N₂), and argon (Ar) (e.g., the second plasma sequence) for a time period of about 0.35 seconds, followed by exposing the semiconductor substrate to a plasma comprising nitrogen (N₂) and argon (Ar) (e.g., the first plasma sequence) for a time period of about 0.65 seconds, without treating the aluminum oxide (Al₂O₃) film, resulted in the presence of blisters in the film stack.

It has been found that exposing a semiconductor substrate (having an aluminum oxide (Al₂O₃) film formed directly on the semiconductor substrate) to a plasma mixture of ammonia (NH₃), nitrogen (N₂), and argon (Ar) (e.g., the second plasma sequence) for a time period of about 0.35 seconds, followed by exposing the semiconductor substrate to a plasma comprising nitrogen (N₂) and argon (Ar) (e.g., the first plasma sequence) for a time period of about 0.65 seconds, including treating the aluminum oxide (Al₂O₃) film with a plasma comprising nitrogen (N₂) prior to the silicon nitride (SiₓN_{y}) deposition in accordance with one or more embodiments of the present disclosure, advantageously resulted in no blisters being present in the film stack.

It has been found that exposing a semiconductor substrate (having an aluminum oxide (Al₂O₃) film formed directly on the semiconductor substrate) to a plasma mixture of ammonia (NH₃), nitrogen (N₂), and argon (Ar) (e.g., the second plasma sequence) for a time period of about 0.35 seconds, followed by exposing the semiconductor substrate to a plasma comprising nitrogen (N₂) and argon (Ar) (e.g., the first plasma sequence) for a time period of about 1 second, without treating the aluminum oxide (Al₂O₃) film, advantageously resulted in no blisters being present in the film stack.

### Example 3—Exposure to First Plasma Sequence, Followed by Exposure to Second Plasma Sequence, Followed by Exposure to Third Plasma Sequence

It has been found that exposing a semiconductor substrate (having an aluminum oxide (Al₂O₃) film formed directly on the semiconductor substrate) to a plasma comprising nitrogen (N₂) and argon (Ar) (e.g., the first plasma sequence) for a time period of about 0.8 seconds, followed by exposing the semiconductor substrate to a plasma mixture of ammonia (NH₃), nitrogen (N₂), and argon (Ar) (e.g., the second plasma sequence) for a time period of about 0.4 seconds, followed by exposing the semiconductor substrate to a plasma comprising nitrogen (N₂) and argon (Ar) (e.g., the third plasma sequence) for a time period of about 0.2 seconds, without treating the aluminum oxide (Al₂O₃) film, advantageously resulted in no blisters being present in the film stack.

Referring again to FIG. 2A, after depositing the silicon nitride (SiₓN_{y}) film 56 at operation 14, the semiconductor substrate 50 is evaluated to determine whether or not the silicon nitride (SiₓN_{y}) film 56 has reached a predetermined thickness or a predetermined number of cycles (of the PEALD process) have been performed. If the predetermined thickness has been met or the predetermined number of cycles (of the PEALD process) have been performed, the method 10 continues to optional post-processing operation 15. The optional post-processing operation 15 can be any suitable process known to the skilled artisan. If the predetermined thickness has not been met or the predetermined number of cycles (of the PEALD process) have not been performed, the method 10 returns to the beginning of the PEALD process. One or more embodiments of the method 10 comprise repeating one or more operations of the method 10 to deposit the silicon nitride (SiₓN_{y}) film 56 to a predetermined thickness and/or until a predetermined number of cycles have been performed.

In one or more embodiments, the method 10 comprises operation 11, operation 12, operation 13, operation 14, and operation 15. In one or more embodiments, the method 10 consists essentially of operation 11, operation 12, operation 13, operation 14, and operation 15. In one or more embodiments, the method 10 consists of operation 11, operation 12, operation 13, operation 14, and operation 15.

The methods described herein may be performed in any suitable processing chamber or processing system (such as the processing tools described herein, for example). The methods described herein may be performed in, for example, a PEALD processing chamber.

Additional embodiments of the disclosure are directed to processing tools. In some embodiments, the processing tool comprises: a central transfer station comprising a robot configured to move a semiconductor substrate (e.g., the semiconductor substrate 50), a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises an atomic layer deposition (ALD) chamber. In some embodiments, the plurality of process stations comprises a plasma-enhanced atomic layer deposition (PEALD) chamber. In some embodiments, the controller is configured to activate the robot to move the semiconductor substrate (e.g., the semiconductor substrate 50) between process stations, and to control a method, such as the method 10.

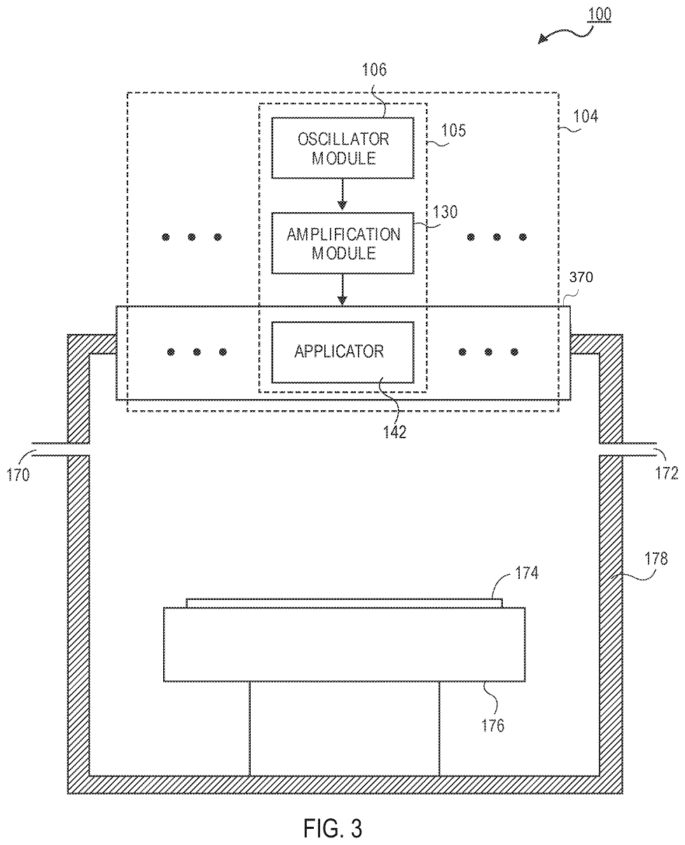

In accordance with one or more embodiments, FIG. 3 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma-enhanced atomic layer deposition (PEALD), etch and selective removal processes, and plasma cleaning. One or more of the operations of method 10 can be performed in the processing tool 100.

The processing tool 100 includes a semiconductor processing chamber 178. In one or more embodiments, the semiconductor processing chamber 178 is a vacuum chamber. In one or more unillustrated embodiments, the vacuum chamber may include a pump for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through a plasma showerhead assembly, e.g., assembly 370 for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alter-native embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. The oscillator module 106 may include a plurality of oscillator modules 106. The applicators 142 are schematically shown as being integrated into the dielectric faceplate 350. The skilled artisan will appreciate that the disclosure is not limited to the applicators 142 being integrated into the assembly 370.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

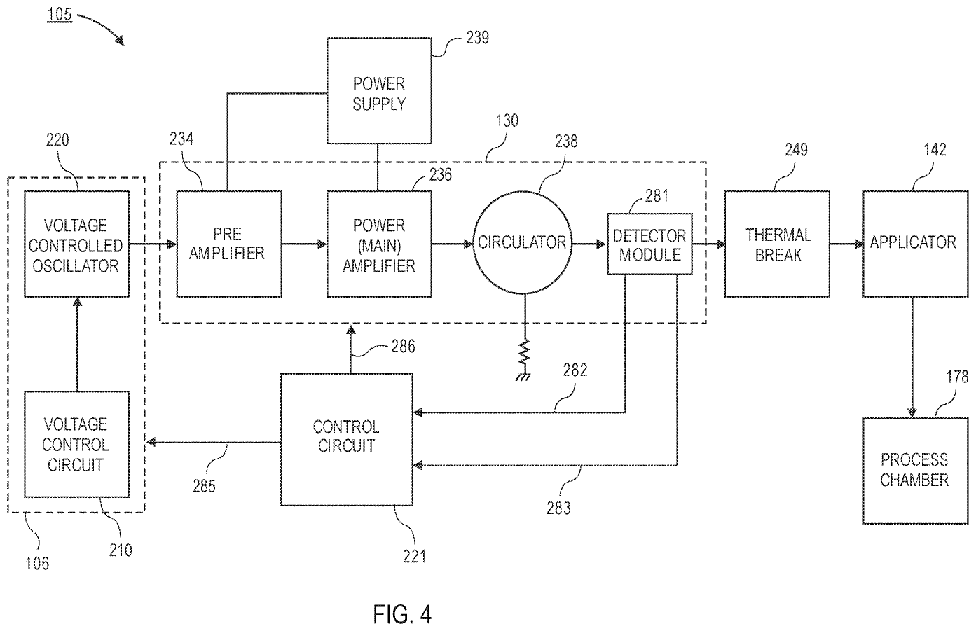

FIG. 4 illustrates a block diagram of a high-frequency emission module 105. In one or more embodiments, the high-frequency emission module 105 comprises the plurality of oscillator modules 106. Each oscillator module 106 may independently include a voltage control circuit 210 for providing an input voltage to a voltage controlled oscillator 220 in order to produce high-frequency electromagnetic radiation at a desired frequency. One or more embodiments include an input voltage in a range of from 1 V to 10V of DC. In one or more embodiments, the voltage controlled oscillator 220 is an electronic oscillator whose oscillation frequency is controlled by the input voltage. According to one or more embodiments, the input voltage from the voltage control circuit 210 results in the voltage controlled oscillator 220 oscillating at a desired frequency. In some embodiments, the high-frequency electromagnetic radiation has a frequency in a range of from about 0.1 MHz to about 30 MHz. In some embodiments, the high-frequency electromagnetic radiation has a frequency in a range of from about 30 MHz to about 300 MHz. In some embodiments, the high-frequency electro-magnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage controlled oscillator 220 to the amplification module 130. The amplification module 130 may include a driver/pre-amplifier 234 and a main power amplifier 236, and each of the driver/pre-amplifier 234 and the main power amplifier 236 are independently coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249.

Accordingly, one or more embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

In some embodiments, a total delivered power from the microwave source is equal to level of forward power 283 minus the level of reflected power 282. In some embodiments, the total delivered power from microwave source is in a range of about 2300 Watts (W) to about 3800 Watts (W), such as, for example, 3325 Watts (W).

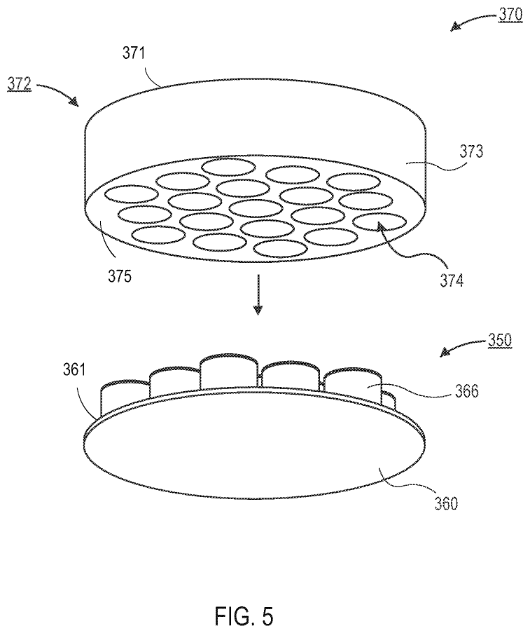

Referring now to FIG. 5, a schematic exploded perspective view of a plasma showerhead assembly, e.g., assembly 370 is shown.

The assembly 370 comprises a conductive plate 372 and a dielectric faceplate 350. As indicated by the arrow, the conductive plate 372 fits over and around the dielectric faceplate 350. In the illustrated embodiment, the assembly 370 is shown as having a substantially circular shape. However, the skilled artisan will appreciate that the assembly 370 may have any suitable shape such as polygonal, elliptical, wedge shaped, or the like.

The conductive plate 372 comprises a conductive body 373 including a first surface 371 and a second surface 375 opposite to the first surface defining a conductive plate thickness, a plurality of resonator openings 374 extending from the first surface 371 through the conductive plate 372 to the second surface 375 of the conductive plate 372, gas channels within the conductive plate thickness, a plurality of conductive plate gas openings on the second surface 375 of the conductive plate 372 in fluid communication with the gas channels within the conductive plate thickness.

In some embodiments, the dielectric faceplate 350 comprises a first surface 361 and a second surface 360 opposite to the first surface 361 defining a dielectric faceplate thickness, a plurality of dielectric resonators 366 protruding from the first surface 361 and configured so that the resonators 366 fit into the plurality of the resonator openings 374 of the conductive plate 372 when assembled, each resonator 366 having a geometric center; and a plurality of dielectric faceplate gas openings extending through the dielectric faceplate thickness.

In some embodiments, monopole antennas 588 may extend into holes 365 in the dielectric resonators 366. The monopole antennas 588 are each electrically coupled to power sources (e.g., high-frequency emission modules 105).

The dielectric faceplate 350 may include any number of dielectric resonators 366. The plurality of dielectric resonators 366 can be arranged in any suitable arrangement. In some embodiments, the plurality of dielectric resonators 366 are arranged in a manner such that the dielectric resonators 366 uniformly distribute the microwave plasma in a semiconductor processing chamber. In some embodiments, the plurality of dielectric resonators 366 are arranged in a manner such that the dielectric resonators 366 uniformly distribute the microwave plasma in a processing chamber, such as, for example, a 300 mm chamber. In some embodiments, each dielectric resonator 366 is configured to provide up to 200 Watts (W) of power. In some embodiments, the total delivered power from microwave source is in a range of about 2300 Watts (W) to about 3800 Watts (W), such as, for example, 3325 Watts (W).

The conductive body 373 may include any suitable conductive material. For example, the conductive body 373 may be aluminum or the like. The plurality of resonator openings 374 may pass entirely through a thickness of the conductive body 373. The resonator openings 374 may be sized to receive the dielectric resonators 366. For example, as the conductive plate 372 is displaced towards the dielectric faceplate 350 (as indicated by the arrow in FIG. 5) the dielectric resonators 366 will be inserted into the plurality of resonator openings 374.

In the illustrated embodiment of FIG. 5, the conductive plate 372 is shown as a single conductive body 373. However, the skilled artisan will appreciate that the conductive plate 372 may comprise one or more discrete conductive components. The discrete components may be individually grounded, or the discrete components may be joined mechanically or by any form of metallic bonding, to form a single electrically conductive body 373.

In some embodiments, the dielectric faceplate 350 and the plurality of dielectric resonators 366 are a monolithic structure. That is, in embodiments where the dielectric faceplate 350 and the plurality of dielectric resonators 366 are a monolithic structure, there is no physical interface between a bottom of the dielectric resonators 366 and the dielectric faceplate 350. As used herein, a “physical interface” refers to a first surface of a first discrete body contacting a second surface of a second discrete body.

In other embodiments, the dielectric faceplate 350 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the dielectric faceplate 350 comprises a dielectric material. For example, the dielectric faceplate 350 may be a ceramic material. In some embodiments, one suitable ceramic material that may be used for the dielectric faceplate 350, as an example, is aluminum oxide (Al₂O₃). In specific embodiments where the dielectric faceplate 350 and the plurality of dielectric resonators 366 are a monolithic structure, the monolithic structure may be fabricated from a single block of material. In other embodiments, a rough shape of the dielectric faceplate 350 may be formed with a molding process, and subsequently machined to provide the final structure with the desired dimensions. For example, green state machining and firing may be used to provide the desired shape of the dielectric faceplate 350. In the illustrated embodiment, the dielectric resonators 366 are shown as having a circular cross-section (when viewed along a plane parallel to the dielectric faceplate 350). However, the skilled artisan will appreciate that the dielectric resonators 366 may comprise many different cross-sections. For example, the cross-section of the dielectric resonators 366 may have any shape that is centrally symmetric.

In one or more unillustrated embodiments, the dielectric faceplate 350 includes one or more rings configured to separate the sidewall of the plurality of resonator openings 374 in the conductive plate 372 from the sidewall of the dielectric resonator 366. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the dielectric faceplate 350 and provides improved coupling of the high-frequency electromagnetic radiation into the processing chamber, such as semiconductor processing chamber 178.

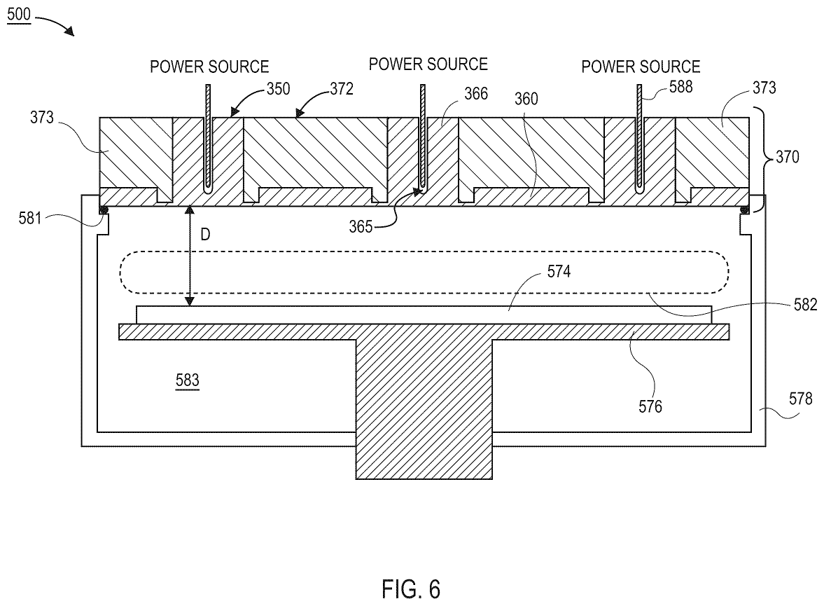

FIG. 6 illustrates a cross-sectional view of a processing tool 500 according to one or more embodiments. In one or more embodiments, the processing tool 500 comprises a semiconductor processing chamber 578 that is sealed by an assembly 370. For example, the assembly 370 may rest against one or more o-rings 581 to provide a vacuum seal to an interior volume 583 of the semiconductor processing chamber 578. In other embodiments, the assembly 370 may interface with the semiconductor processing chamber 578. That is, the assembly 370 may be part of a lid that seals the semiconductor processing chamber 578. In some embodiments, the processing tool 500 may comprise a plurality of processing volumes (which may be fluidically coupled together), with each processing volume independently having a plasma showerhead assembly, such as, for example the assembly 370. One or more of the operations of method 10 can be performed in the processing tool 500.

In some embodiments, a chuck 576 or the like may support a workpiece 574 (e.g., wafer, substrate, etc.). In one or more embodiments, the assembly 370 is spaced a distance D from the workpiece 574. The distance D may be any suitable distance. In some embodiments, the interior volume 583 may be suitable for striking a plasma 582. That is, the semiconductor processing chamber 578 may be a vacuum chamber.

In one or more embodiments, the semiconductor substrate 50 is the substrate 174 in the processing tool 100. In one or more embodiments, the semiconductor substrate 50 is the workpiece 574 in the processing tool 500. The method 10 described herein may be implemented in any of the processing tools described herein.

One or more embodiments of the disclosure are directed to a non-transitory computer readable medium including instructions, that, when executed by a controller of a processing chamber, cause the processing chamber to perform one or more of the operations of method 10.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method comprising:
depositing an aluminum oxide (Al₂O₃) film on a semiconductor substrate; and
depositing a silicon nitride (SiₓN_{y}) film directly on the aluminum oxide (Al₂O₃) film.

2. The method of claim 1, further comprising treating the aluminum oxide (Al₂O₃) film with a plasma comprising nitrogen (N₂) prior to depositing the silicon nitride (SiₓN_{y}) film.

3. The method of claim 2, wherein the aluminum oxide (Al₂O₃) film is treated with the plasma for a time period in a range of from 0.1 seconds to 2 minutes.

4. The method of claim 1, wherein the semiconductor substrate comprises one or more of silicon (Si) or silicon oxide (SiOx).

5. The method of claim 1, wherein depositing the aluminum oxide (Al₂O₃) film comprises an atomic layer deposition (ALD) process.

6. The method of claim 1, wherein depositing the silicon nitride (SiₓN_{y}) film comprises a plasma-enhanced atomic layer deposition (PEALD) process.

7. The method of claim 6, wherein the PEALD process comprises:
exposing the semiconductor substrate to a silicon-containing precursor; and
exposing the semiconductor substrate to a nitrogen-containing plasma mixture comprising argon (Ar) and one or more of ammonia (NH₃) or nitrogen (N₂).

8. The method of claim 7, wherein the nitrogen-containing plasma mixture consists essentially of nitrogen (N₂) and argon (Ar).

9. The method of claim 7, wherein the nitrogen-containing plasma mixture consists essentially of ammonia (NH₃) and argon (Ar).

10. The method of claim 7, wherein the semiconductor substrate is exposed to the nitrogen-containing plasma mixture for a time period in a range of from 0.2 seconds to 4 seconds.

11. The method of claim 10, wherein exposing the semiconductor substrate to the nitrogen-containing plasma mixture comprises a first plasma sequence and a second plasma sequence.

12. The method of claim 11, wherein the first plasma sequence comprises exposing the semiconductor substrate to nitrogen (N₂) and argon (Ar).

13. The method of claim 11, wherein the second plasma sequence comprises exposing the semiconductor substrate to ammonia (NH₃) and argon (Ar).

14. The method of claim 11, wherein the second plasma sequence is performed prior to the first plasma sequence.

15. The method of claim 11, wherein exposing the semiconductor substrate to the nitrogen-containing plasma mixture further comprises a third plasma sequence.

16. The method of claim 15, wherein the first plasma sequence comprises exposing the semiconductor substrate to nitrogen (N₂) and argon (Ar), the second plasma sequence comprises exposing the semiconductor substrate to ammonia (NH₃) and argon (Ar), and the third plasma sequence comprises exposing the semiconductor substrate to nitrogen (N₂) and argon (Ar).

17. The method of claim 2, comprising repeating one or more operations of the method to deposit the silicon nitride (SiₓN_{y}) film to a predetermined thickness.

18. The method of claim 2, wherein the plasma comprising nitrogen (N₂) is a microwave plasma generated by a microwave plasma source.

19. The method of claim 7, wherein the nitrogen-containing plasma mixture is a microwave plasma generated by a microwave plasma source.

20. A method comprising:
treating an aluminum oxide (Al₂O₃) film on a semiconductor substrate with a plasma comprising nitrogen (N₂) for a time period in a range of from 0.1 seconds to 2 minutes, the plasma comprising a microwave plasma generated by a microwave plasma source; and
depositing a silicon nitride (SiₓN_{y}) film directly on the aluminum oxide (Al₂O₃) film, wherein depositing the silicon nitride (SiₓN_{y}) film comprises a plasma-enhanced atomic layer deposition (PEALD) process comprising:
exposing the semiconductor substrate to a silicon-containing precursor; and
exposing the semiconductor substrate to a nitrogen-containing plasma mixture comprising argon (Ar) and one or more of ammonia (NH₃) or nitrogen (N₂), wherein the semiconductor substrate is exposed to the nitrogen-containing plasma mixture for a time period in a range of from 0.2 seconds to 4 seconds, and the nitrogen-containing plasma mixture comprises a microwave plasma generated by the microwave plasma source.
